(19) United States
(12) Patent Application Publication
(10) Pub. No.: US 2025/0380442 A1
(43) Pub. Date: Dec. 11, 2025

(54) SEMICONDUCTOR STRUCTURE WITH CONDUCTIVE STRUCTURE AND METHOD FOR MANUFACTURING THE SAME

(71) Applicant: Taiwan Semiconductor Manufacturing Company, Ltd, Hsinchu (TW)

(72) Inventors: Jung-Hung Chang, Yuanlin city (TW); Shih-Cheng CHEN, New Taipei City (TW); Tsung-Han CHUANG, Tainan City (TW); Fu-Cheng CHANG, Hsinchu City (TW); Pei-Yu Wang, Hsinchu City (TW); Kuo-Cheng CHIANG, Zhubei Township (TW)

(73) Assignee: Taiwan Semiconductor Manufacturing Company, Ltd, Hsinchu (TW)

(21) Appl. No.: 18/890,102

(22) Filed: Sep. 19, 2024

Related U.S. Application Data
(60) Provisional application No. 63/656,270, filed on Jun. 5, 2024.

(51) Int. Cl. H01L 29/775; H01L 21/285; H01L 21/764; H01L 29/06; H01L 29/08; H01L 29/423; H01L 29/66; H01L 29/786

(52) U.S. Cl. CPC H10D 30/43; H01L 21/28518; H01L 21/764; H10D 30/014; H10D 30/6735; H10D 30/6757; H10D 62/121; H10D 62/151; H10D 64/017; H10D 64/018

(57) ABSTRACT

Semiconductor structures and methods for forming the same are provided. The semiconductor structure includes a plurality of first nanostructures formed over a substrate, and a first gate structure formed on the first nanostructures. The semiconductor structure includes a first S/D structure formed adjacent to the first gate structure. The semiconductor structure includes a dielectric layer directly below the first S/D structure. The dielectric layer has an air gap. The dielectric layer is in direct contact with the bottommost first nanostructure.

### CROSS REFERENCE TO RELATED APPLICATIONS

This application claims the benefit of U.S. Provisional Application No. 63/656,270 filed on Jun. 5, 2024, the entirety of which is incorporated by reference herein.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIGS. 2A-1 to 2P-1 illustrate cross-sectional representations of various stages of manufacturing the semiconductor structure shown along line A-A′ in FIG. 1E in accordance with some embodiments.

FIGS. 2A-2 to 2P-2 illustrate cross-sectional representations of various stages of manufacturing the semiconductor structure shown along line B-B′ in FIG. 1E in accordance with some embodiments.

FIG. 2P′-1 and 2P′-2 illustrate a cross-sectional views of a semiconductor structure, in accordance with some embodiments.

FIG. 2P″-1 and 2P″-2 illustrate a cross-sectional views of a semiconductor structure, in accordance with some embodiments.

FIGS. 3A-1 and 3A-2 illustrate cross-sectional representations of the semiconductor structure shown along line C-C′ in FIG. 1E in accordance with some embodiments.

FIG. 4A-1 and 4A-2 illustrate a cross-sectional views of a semiconductor structure, in accordance with some embodiments.

FIG. 5A-1 and 5A-2 illustrate a cross-sectional views of a semiconductor structure, in accordance with some embodiments.

FIG. 6A-1 and 6A-2 illustrate a cross-sectional views of a semiconductor structure, in accordance with some embodiments.

FIG. 7A-1 and 7A-2 illustrate a cross-sectional views of a semiconductor structure, in accordance with some embodiments.

FIG. 8A-1 and 8A-2 illustrate a cross-sectional views of a semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a substrate includes a first region and a second region. A number of first nanostructures are formed on the first region, and a number of second nanostructures are formed on the second region. A first S/D structure formed adjacent to the first nanostructures, and a second S/D structure formed adjacent to the second nanostructures. There is a dielectric layer below the first S/D structure in the first region. The dielectric layer has an air gap. The dielectric layer is in direct contact with the bottommost first nanostructure in the first region, and thus the bottommost first nanostructure become inactive. The effective (or active) nanostructures are controlled by defining the location of the dielectric layer in the first region. In the second region, no dielectric layer is directly below the second S/D structure, and the bottommost second nanostructure is still active. More effective (or active) nanostructures can improve the speed of the semiconductor structure, fewer effective (or active) nanostructures can increase the power efficiency. Therefore, the semiconductor structure includes more effective (or active) nanostructures in the second region for speed performance considerations and fewer effective (or active) nanostructures in the first region for power efficiency consideration. Therefore, the performance of semiconductor structure is improved. The source/drain (S/D) region(s) or the source/drain (S/D) structure(s) may refer to a source or a drain, individually or collectively dependent upon the context.

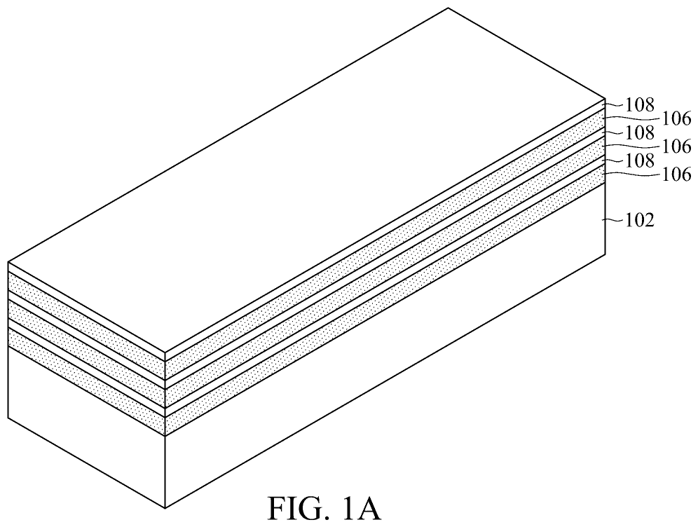

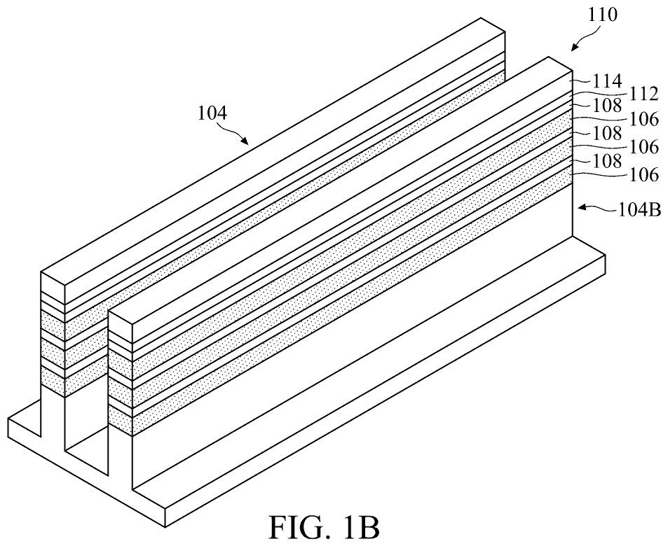

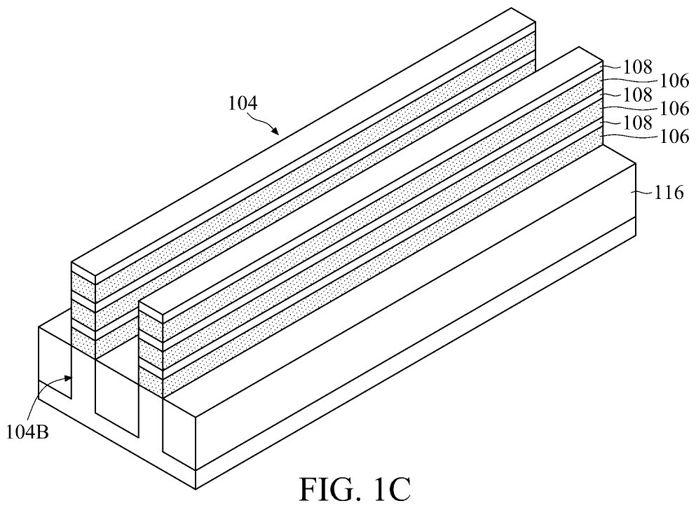

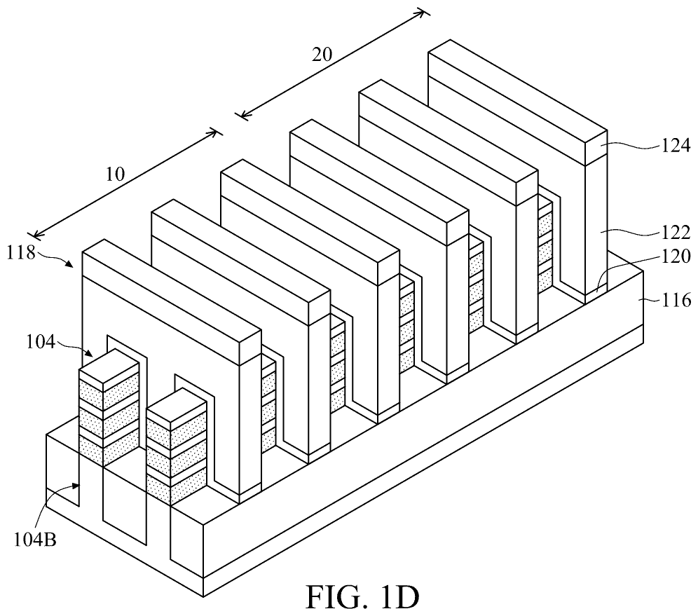

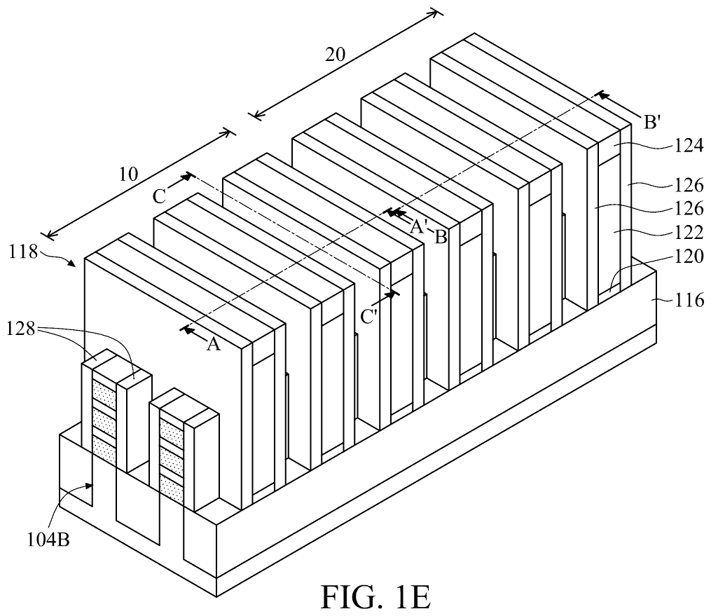

FIGS. 1A to 1E illustrate perspective views of intermediate stages of manufacturing a semiconductor structure 100a, in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

As shown in FIG. 1B, after the first semiconductor material layers 106 and the second semiconductor material layers 108 are formed as a semiconductor material stack over the substrate 102, the semiconductor material stack is patterned to form a fin structure 104, in accordance with some embodiments. In some embodiments, the fin structure 104 includes a base fin structure 104B and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-temperature chemical vapor deposition (LPCVD) or plasma-enhanced CVD (PECVD).

As shown in FIG. 1C, after the fin structure 104 is formed, an isolation structure 116 is formed around the fin structure 104, and the mask structure 110 is removed, in accordance with some embodiments. The isolation structure 116 is configured to electrically isolate active regions (e.g. the fin structure 104) of the semiconductor structure 100 and is also referred to as shallow trench isolation (STI) feature in accordance with some embodiments.

The isolation structure 116 may be formed by depositing an insulating layer over the substrate 102 and recessing the insulating layer so that the fin structure 104 is protruded from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

As shown in FIG. 1D, after the isolation structure 116 is formed, dummy gate structures 118 are formed across the fin structure 104 and extend over the isolation structure 116, in accordance with some embodiments. The dummy gate structures 118 may be used to define the source/drain regions and the channel regions of the resulting semiconductor structure 100.

In some embodiments, the dummy gate structures 118 include dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

In some embodiments, hard mask layers 124 are formed over the dummy gate structures 118. In some embodiments, the hard mask layers 124 include multiple layers, such as an oxide layer and a nitride layer. In some embodiments, the oxide layer is silicon oxide, and the nitride layer is silicon nitride.

The formation of the dummy gate structures 118 may include conformally forming a dielectric material as the dummy gate dielectric layers 120. Afterwards, a conductive material may be formed over the dielectric material as the dummy gate electrode layers 122, and the hard mask layer 124 may be formed over the conductive material. Next, the dielectric material and the conductive material may be patterned through the hard mask layer 124 to form the dummy gate structures 118.

As shown in FIG. 1E, after the dummy gate structures 118 are formed, gate spacers 126 are formed along and covering opposite sidewalls of the dummy gate structure 118 and fin spacers 128 are formed along and covering opposite sidewalls of the source/drain regions of the fin structure 104, in accordance with some embodiments.

The gate spacers 126 may be configured to separate source/drain structures from the dummy gate structure 118 and support the dummy gate structure 118, and the fin spacers 128 may be configured to constrain a lateral growth of subsequently formed source/drain structure and support the fin structure 104.

In some embodiments, the gate spacers 126 and the fin spacers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacers 126 and the fin spacers 128 may include conformally depositing a dielectric material covering the dummy gate structure 118, the fin structure 104, and the isolation structure 116 over the substrate 102, and performing an anisotropic etching process, such as dry plasma etching, to remove the dielectric layer covering the top surfaces of the dummy gate structure 118, the fin structure 104, and portions of the isolation structure 116.

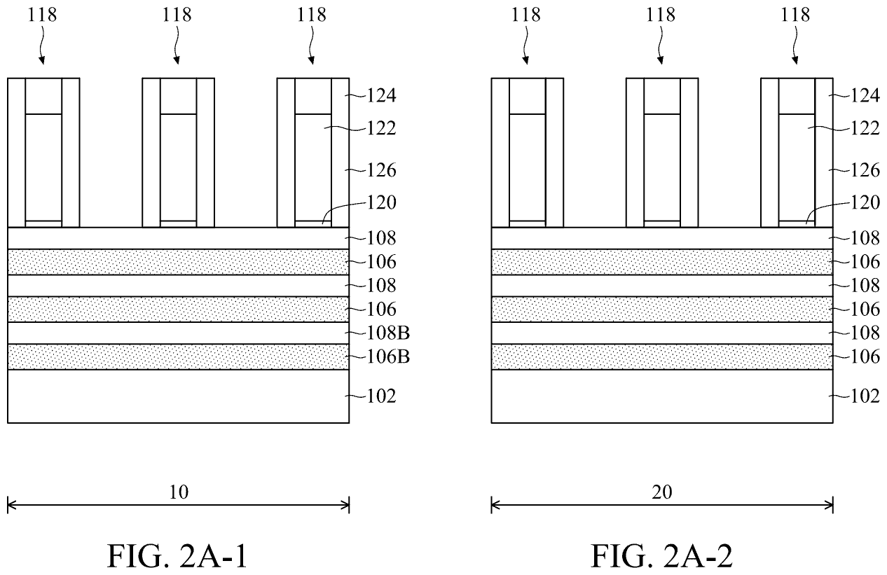

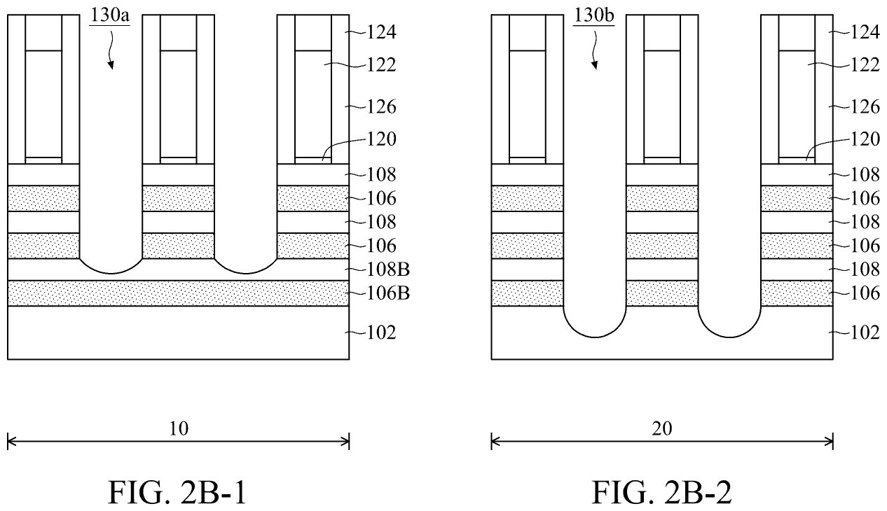

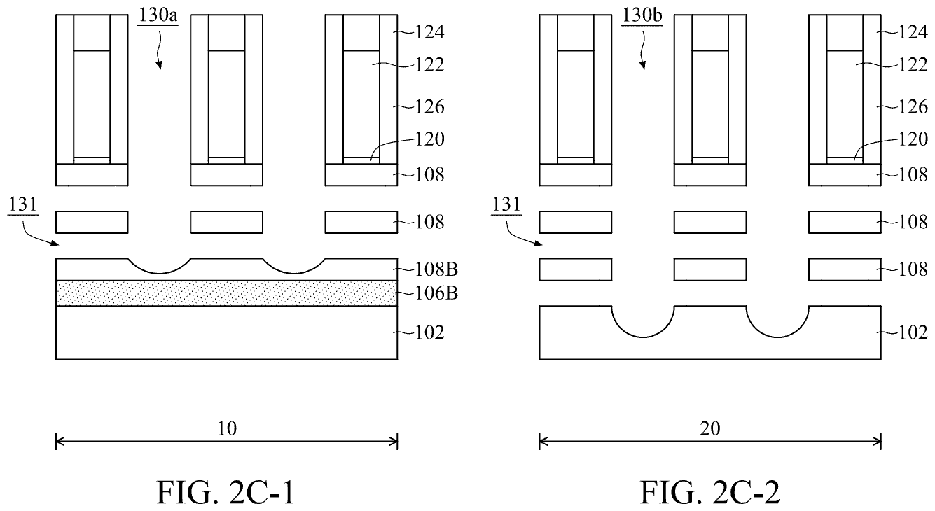

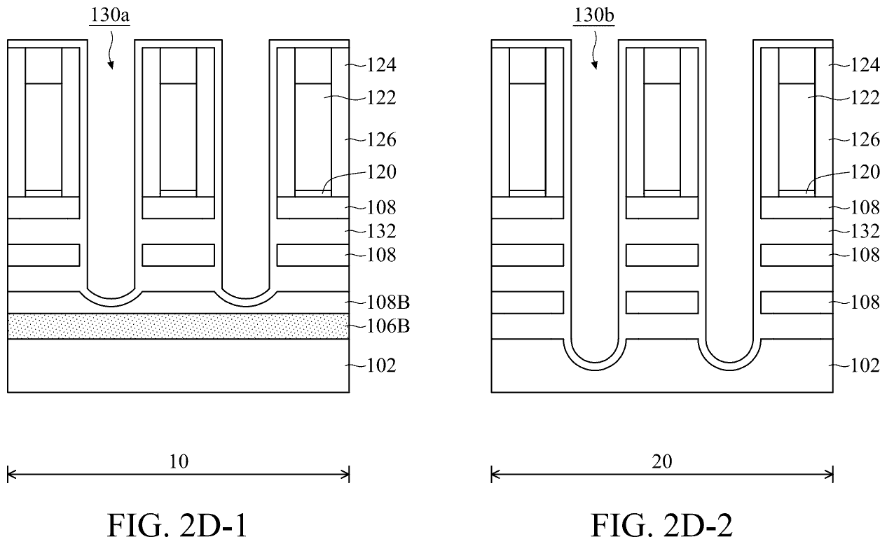

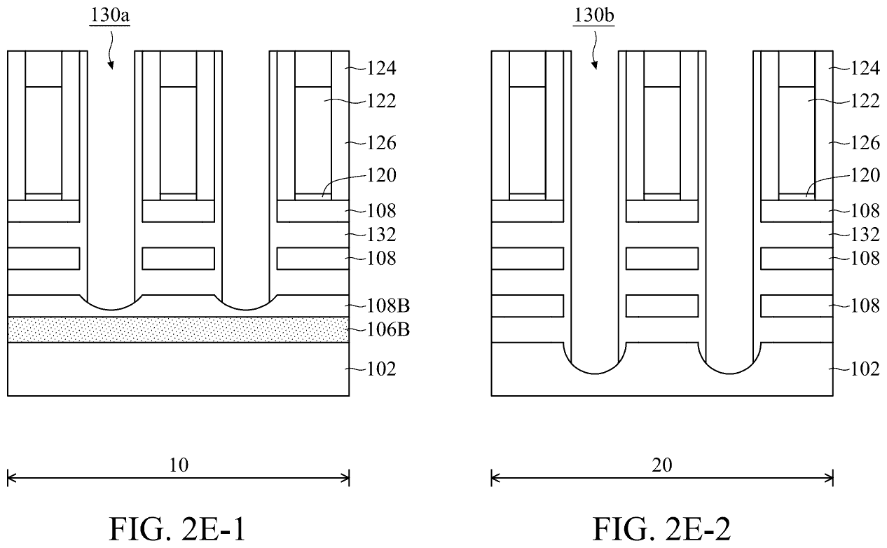

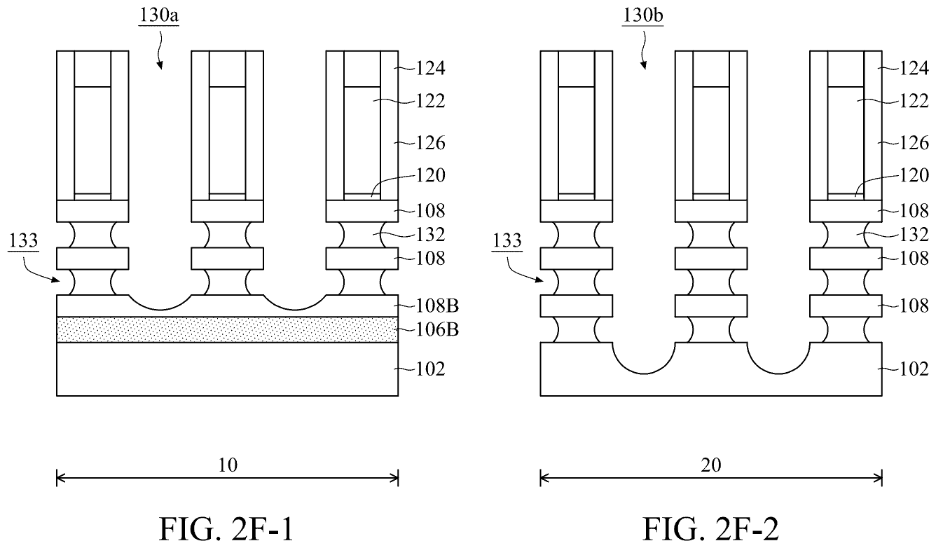

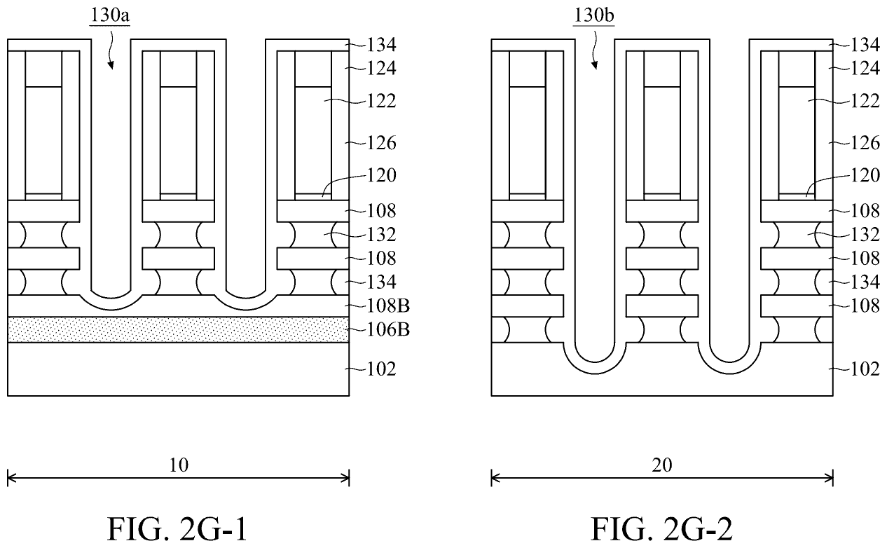

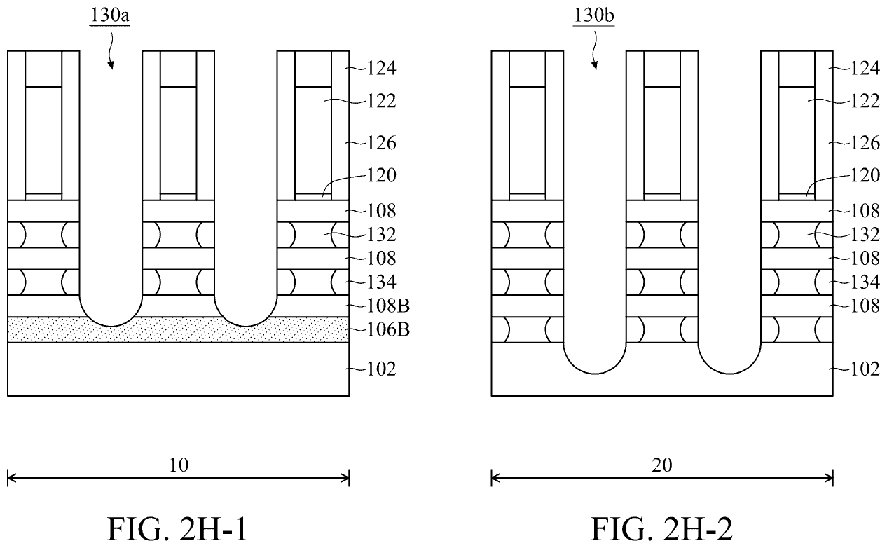

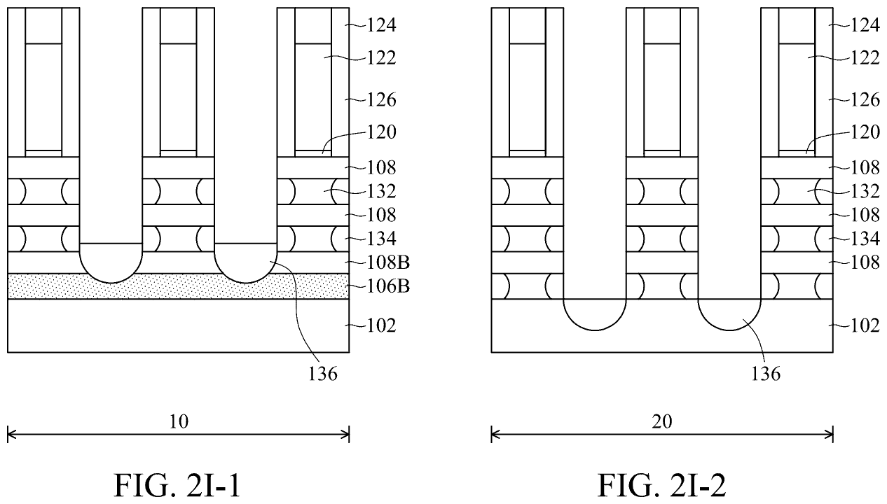

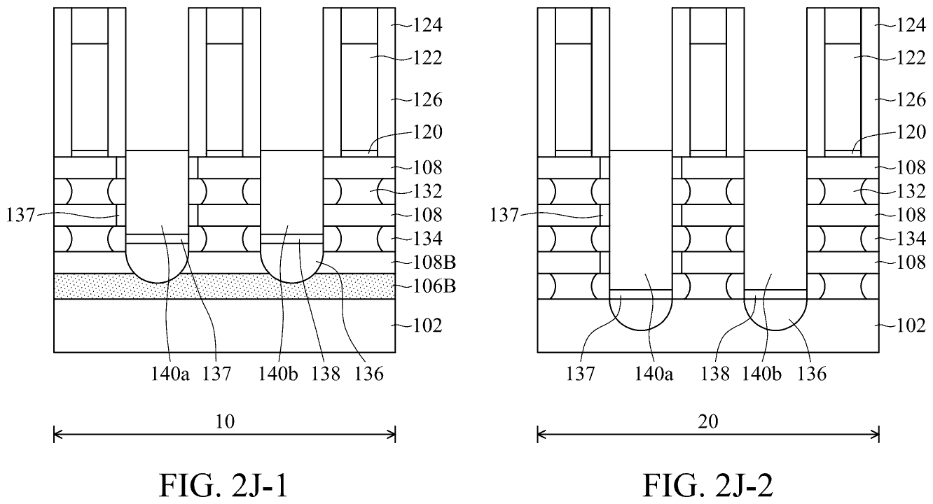

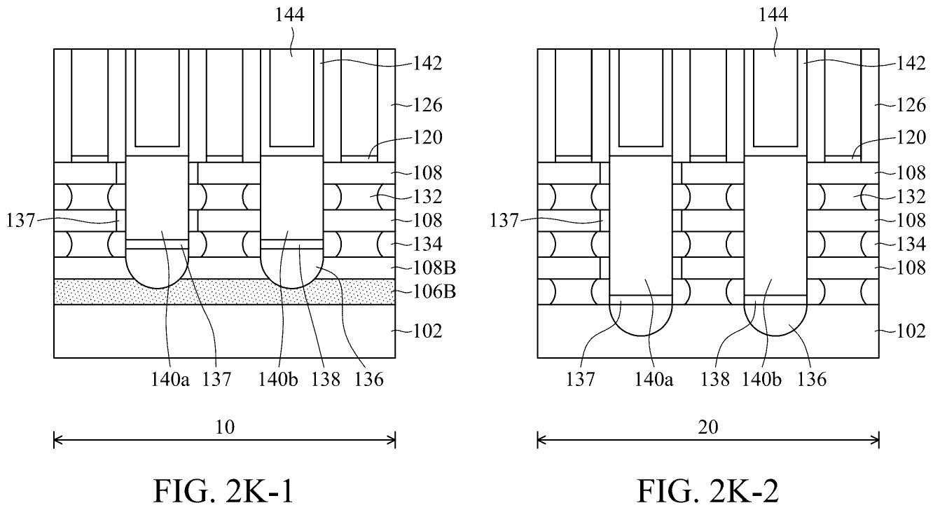

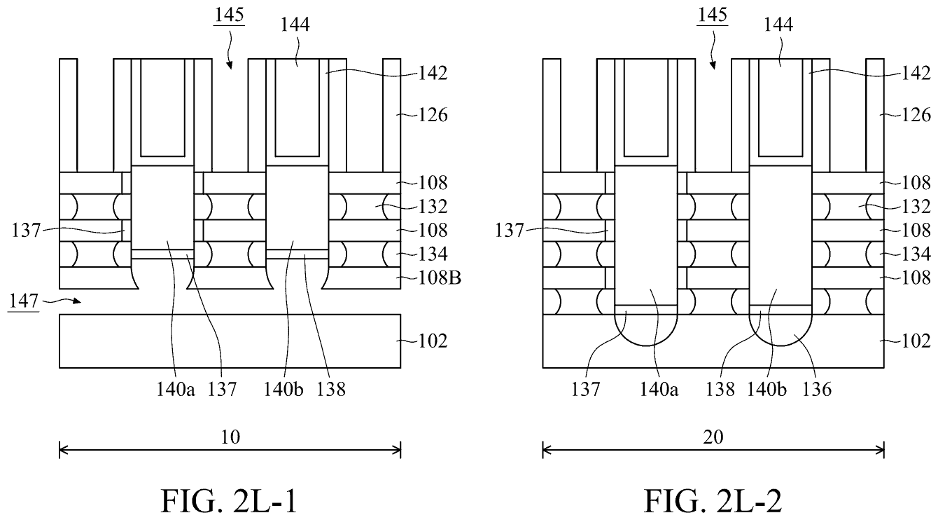

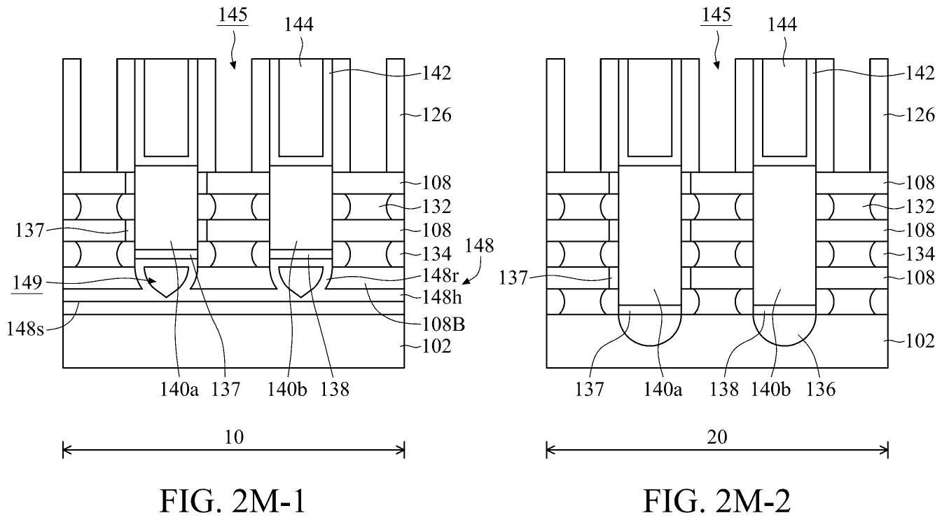

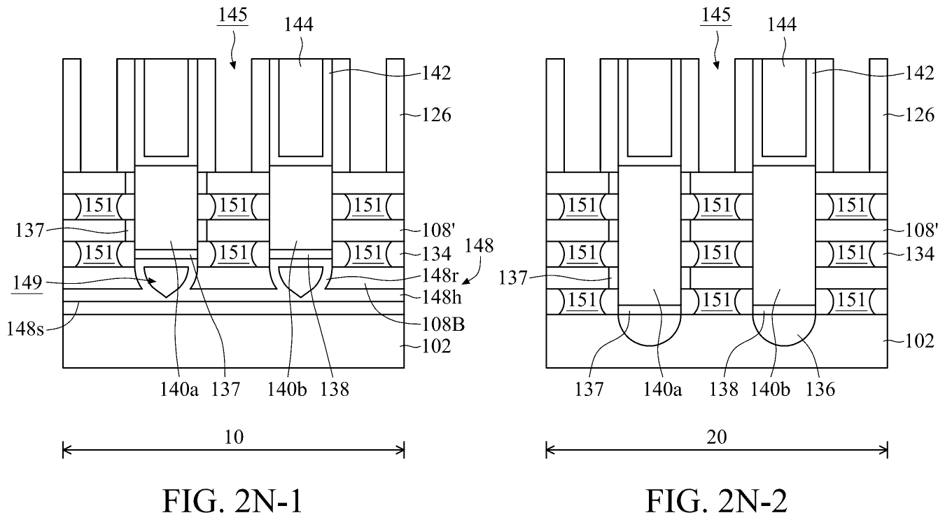

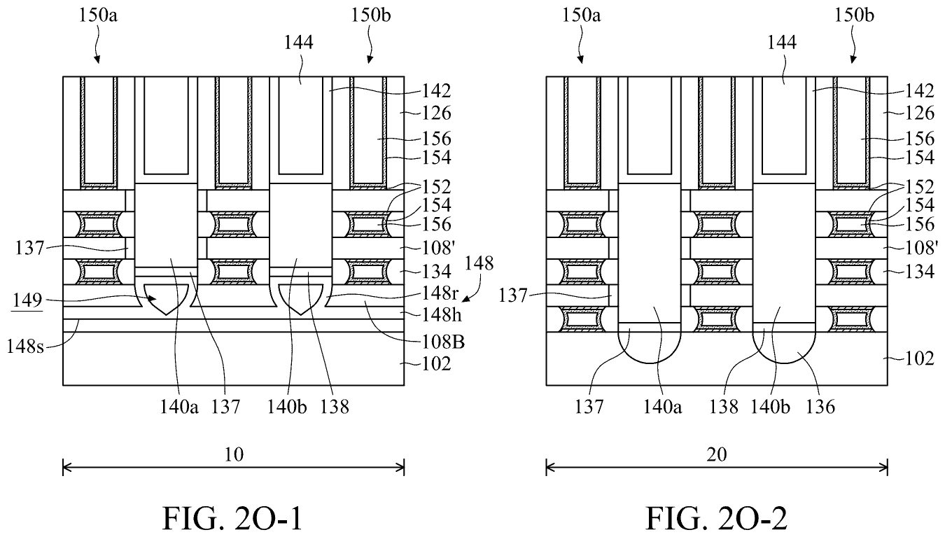

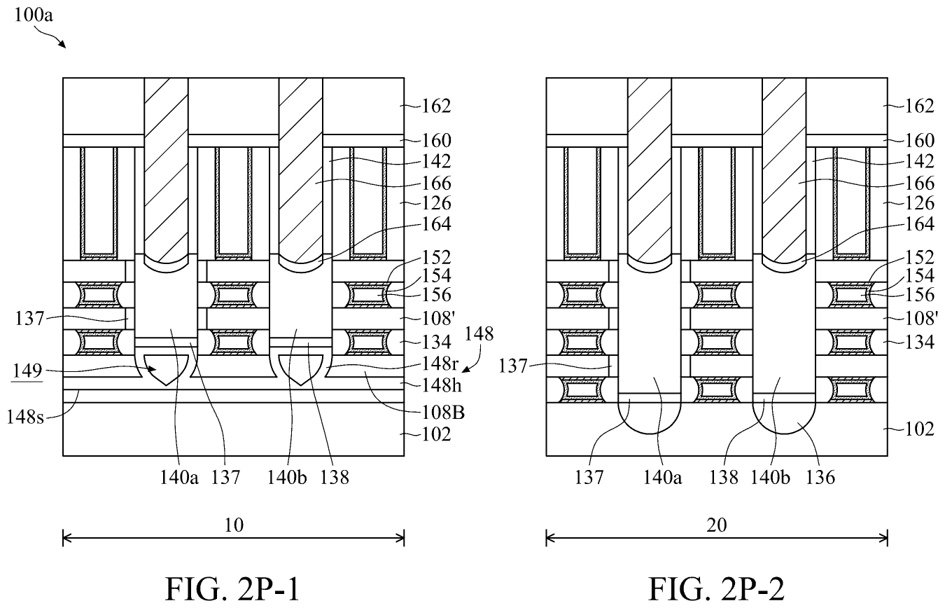

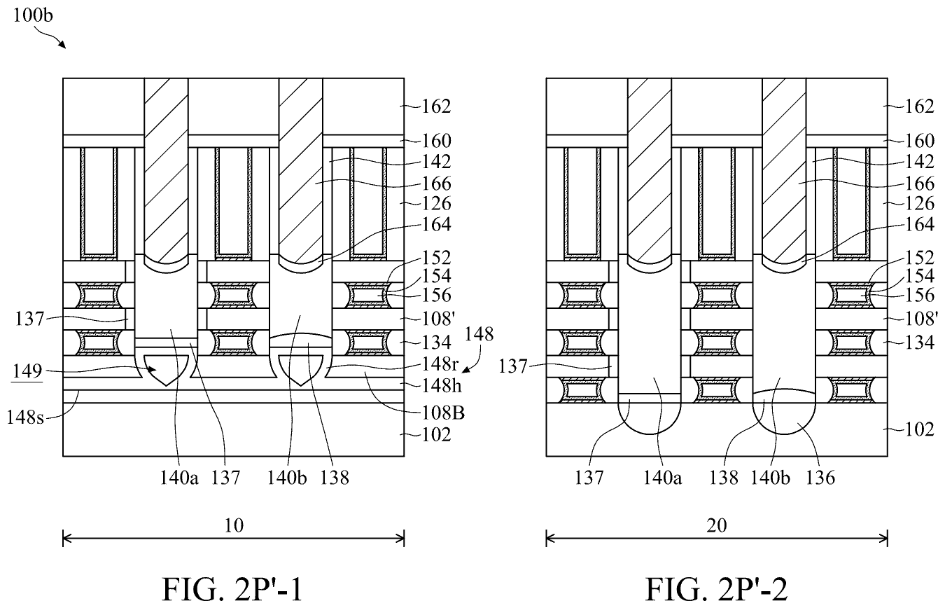

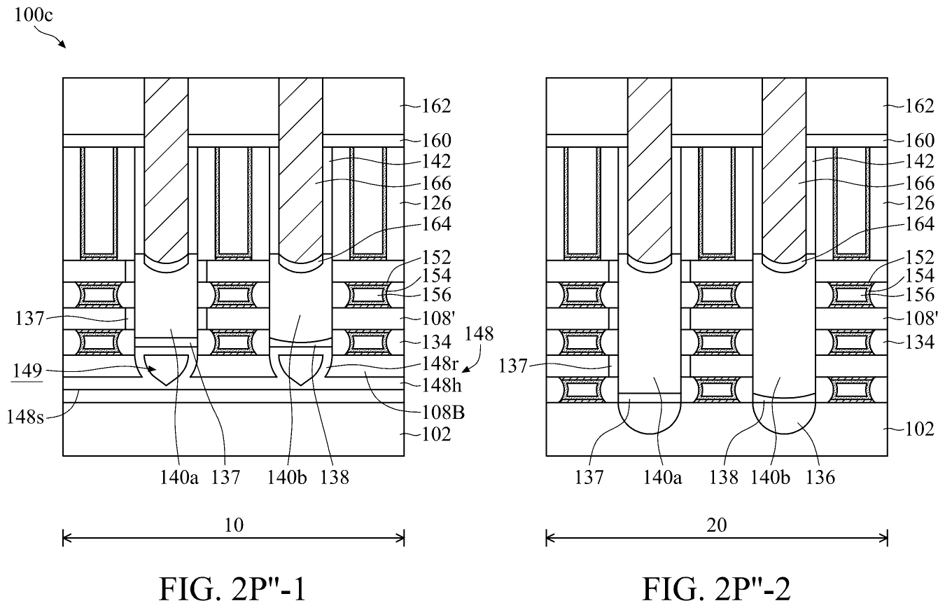

FIGS. 2A-1 to 2P-1 illustrate cross-sectional representations of various stages of manufacturing the semiconductor structure 100a shown along line A-A′ in FIG. 1E in accordance with some embodiments. FIGS. 2A-2 to 2P-2 illustrate cross-sectional representations of various stages of manufacturing the semiconductor structure 100a shown along line B-B′ in FIG. 1E in accordance with some embodiments.

More specifically, FIG. 2A-1 illustrates the cross-sectional representation shown along line A-A′ in FIG. 1E, in accordance with some embodiments. FIG. 2A-2 illustrates the cross-sectional representation shown along line B-B′ in FIG. 1E, in accordance with some embodiments. As shown in FIG. 2A-1, the dummy gate structures 118 are formed in the first region 10. As shown in FIG. 2A-2, the dummy gate structures 118 are formed in the second region 20.

As shown in FIGS. 2B-1 and 2B-2, after the gate spacers 126 and the fin spacers 128 are formed, the source/drain (S/D) regions of the fin structure 104 are recessed to form source/drain (S/D) trenches 130a/130b, as shown in in accordance with some embodiments. More specifically, as shown in FIG. 2B-1, a portion of the first semiconductor material layers 106 and a portion of the second semiconductor material layers 108 are removed. The bottom surface of the S/D trench 130a in the first region 10 is higher than the top surface of the bottommost first semiconductor material layer 106B in the second region 20. The S/D trench 130a in the first region 10 is not through the bottommost first semiconductor material layer 106B. The S/D trench 130a in the first region 10 stops at the bottommost second semiconductor material layer 108B.

As shown in FIG. 2B-2, the first semiconductor material layers 106 and the second semiconductor material layers 108 not covered by the dummy gate structures 118 and the gate spacers 126 are removed to form the S/D trench 130b in the second region 20, in accordance with some embodiments. The S/D trench 130b in the second region 20 is through the bottommost first semiconductor material layer 106B.

In some embodiments, the fin structure 104 is recessed by performing an etching process. The etching process may be an anisotropic etching process, such as dry plasma etching, and the dummy gate structure 118 and the gate spacers 126 are used as etching masks during the etching process.

Afterwards, as shown in FIGS. 2C-1 and 2C-2, after the source/drain trenches 130a/130b are formed, a portion of the second semiconductor material layers 106 are removed to form a recess 131, in accordance with some embodiments. The recess 131 is exposed by the S/D trenches 130a/130b.

As shown in FIG. 2C-1, the bottommost first semiconductor material layer 106B in the first region 10 is not removed. As shown in FIG. 2C-2, all of the first semiconductor material layers 106 in the second region 20 is removed.

Next, as shown in FIGS. 2D-1 and 2D-2, a dummy dielectric layer 132 is formed in the recess 131, in accordance with some embodiments. The dummy dielectric layer 132 is used to replace the second semiconductor material layers 106. As a result, the second semiconductor material layers 108 and the dummy dielectric layer 132 are alternately stacked. The dummy dielectric layer 132 is also called as disposable interposer which will be removed and replaced with a first gate structure 150a and a second gate structure 150b (shown in FIGS. 2O-1 and 2O-2) in the following steps.

The dummy dielectric layer 132 is made of silicon oxide (SiO₂), silicon oxynitride (SiON), aluminum oxide (Al₂O₃) or another applicable materials. In some embodiments, the dummy dielectric layer 132 is formed by an ALD (atomic layer deposition process), flowable CVD or another application process. The advantage of the ALD process is to form uniform and conformal films in the narrow recess 131.

Afterwards, as shown in FIGS. 2E-1 and 2E-2, after the dummy dielectric layer 132 is formed, the horizontal portions of the dummy dielectric layer 132 are removed, in accordance with some embodiments. More specifically, the bottom portion and the top portion of the dummy dielectric layer 132 are removed. In some embodiments, the horizontal portions of the dummy dielectric layer 132 are removed by the anisotropic etching process.

Next, as shown in FIGS. 2F-1 and 2F-2, a portion of the dummy dielectric layer 132 is removed to form notches 133 between adjacent second semiconductor material layers 108. In some embodiments, the etching process is an isotropic etching such as dry chemical etching, remote plasma etching, wet chemical etching, another suitable technique, and/or a combination thereof.

Next, as shown in FIGS. 2G-1 and 2G-2, inner spacers 134 are formed in the notches 133 between the second semiconductor material layers 108, in accordance with some embodiments. The inner spacers 134 are configured to separate the source/drain structures and the gate structures formed in subsequent manufacturing processes in accordance with some embodiments.

The inner spacers 134 and the dummy dielectric layers 132 are made of different materials. The inner spacers 134 has a high etching selectivity with respect to the dummy dielectric layers 132, and the inner spacer layers 134 are not removed when the dummy dielectric layers 132 are removed at the following steps.

In some embodiments, the inner spacers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layer 134 is formed by a deposition process, such as chemical vapor deposition (CVD) process, atomic layer deposition (ALD) process, another applicable process, or a combination thereof.

Afterwards, as shown in FIGS. 2H-1 and 2H-2, a portion of the inner spacers 134 outside of the notches 133 are removed, and a portion of the bottommost first semiconductor material layer 106B is simultaneously removed, in accordance with some embodiments. Therefore, the depth of the S/D trench 130a in the first region 10 is enlarged, and the bottommost first semiconductor material layer 106B is exposed. The exposed bottommost first semiconductor material layer 106B is used to help the formation of a sacrificial layer 136 (shown in FIGS. 21-1 and 21-2). In the following steps, the sacrificial layer 136 is formed on and in direct contact with the bottommost first semiconductor material layer 106B.

The S/D trench 130a in the first region 10 is not through bottommost first semiconductor material layer 106B. The bottommost surface of the S/D trench 130a is higher than the bottom surface of the bottommost first semiconductor material layer 106B. In some embodiments, the bottommost surface of the S/D trench 130a in the first region 10 is higher than the bottommost surface of the S/D trench 130b in the second region 20.

Next, as shown in FIGS. 21-1 and 21-2, a sacrificial layer 136 is formed in the S/D trench 130a in the first region 10, and in the S/D trench 130b in the second region 20, in accordance with some embodiments. In the first region 10, the sacrificial layer 136 is in direct contact with the exposed bottommost first semiconductor material layer 106B.

The sacrificial layer 136 will be removed at the following steps, and will be replaced with other materials. The sacrificial layer 136 is used as a seed layer to help the formation of the source/drain (S/D) structures 140a/140b (formed later). Since the lattice of the sacrificial layer 136 is similar to the lattice of the S/D structure 140a/140b, the quality of the S/D structure 140a/140b is improved. In addition, the sacrificial layer 136 has a high etching selectivity with respect to the second semiconductor material layer 108, and therefore the sacrificial layer 136 is removed while the second semiconductor material layer 108 is not removed at the following steps.

In some embodiments, the sacrificial layer 136 is made of SiGe or another applicable material. In some embodiments, the sacrificial layer 136 and the bottommost first semiconductor material layer 106B are made of the same materials. In some embodiments, the sacrificial layer 136 and the bottommost first semiconductor material layer 106B are made of SiGe.

Afterwards, as shown in FIGS. 2J-1 and 2J-2, an epitaxial layer 137 is formed on the sacrificial layer 136 in the first region 10, and a bottom isolation layer 138 is formed on the sacrificial layer 136 in the second region 20, in accordance with some embodiments. Next, a first source/drain (S/D) structure 140a is formed on the epitaxial layer 137 in the first region 10, and a second S/D structure 140b is formed on the bottom isolation layer 138 in the second region 20, in accordance with some embodiments. In addition, the first S/D structure 140a is formed on the epitaxial layer 137 in the second region 20, and the second S/D structure 140b is formed on the bottom isolation layer 138 in the second region 20.

In some embodiments, the material of first S/D structure 140a is different from the material of the second S/D structure 140b. In some embodiments, the material of first S/D structure 140a is a P-type epitaxial layer. In some embodiments, the material of second S/D structure 140a is a N-type epitaxial layer. It should be noted that the first S/D structure 140a is formed on the epitaxial layer 137, rather than on the dielectric layer, the quality of the first S/D structure 140a is improved. Therefore, when the first S/D structure 140a is a P-type epitaxial layer and the quality of the first S/D structure 140a is improved, the compressive strain effect of the S/D structure 140a can be maintained.

In addition, the epitaxial layer 137 is also formed on sidewall surfaces of the second semiconductor material layers 108. In some embodiments, a portion of the second semiconductor material layers 108 is recessed to form recesses, and the epitaxial layer 137 is formed on the recesses. It should be noted that the epitaxial layer 137 is not formed on the inner spacer layer 134 since the epitaxial layer 137 is formed by the epitaxial growth process.

The epitaxial layer 137 has a bottom portion and a sidewall portion. In some embodiments, the top surface of the bottom portion of the epitaxial layer 137 is lower than the top surface of the bottommost inner spacer layer 134. A portion of the sidewall portion of the epitaxial layer 137 is directly below the gate spacer layer 126. In some other embodiments, no epitaxial layer is formed, and therefore the first S/D structure 140a is directly formed on the sacrificial layer 136.

The epitaxial layer 137 is formed in the first region 10 and the second region 20. The epitaxial layer 137 in the first region 10 is higher than the epitaxial layer 137 in the second region 20.

The epitaxial layer 137 is formed between the sacrificial layer 136 and the first S/D structure 140a. The epitaxial layer 137 is used as an etching stop layer. In some embodiments, the epitaxial layer 137 is formed by epitaxially grown Si doped with boron (B). In addition, the inner spacer layer 134 is also doped with dopants when the epitaxial layer 137 is formed.

In some embodiments, the top surface of the bottom isolation layer 138 is lower than the top surface of the bottommost inner spacer layer 134. In some embodiments, the bottom isolation layer 138 is made of SiN, SiON, SiOCN, SiOC, SiCN, SiOx, AlOx, HfOx or another applicable material. In some embodiments, the bottom isolation layer 138 is formed by a deposition process, such as CVD process, ALD process, another applicable process, or a combination thereof. In some embodiments, the bottom isolation layer 138 is formed by an ALD or an ALD-like process.

In some embodiments, the bottom surface of the first S/D structures 140a in the first region 10 is higher than the bottom surface of the first S/D structure 140a in the second region 20. The height of the first S/D structures 140a in the first region 10 is smaller than the height of the first S/D structure 140a in the second region 20.

In some embodiments, the bottom surface of the second S/D structures 140b in the first region 10 is higher than the bottom surface of the second S/D structure 140b in the second region 20. The height of the second S/D structures 140b in the first region 10 is smaller than the height of the second S/D structure 140b in the second region 20.

In some embodiments, the first S/D structures 140a and the second S/D structure 140b are formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the first S/D structures 140a and the second S/D structure 140b are made of any applicable material, such as Ge, Si, GaAs, AlGaAs, SiGe, GaAsP, SiP, SiC, SiCP, or a combination thereof.

In some embodiments, the first S/D structures 140a and the second S/D structure 140b are in-situ doped during the epitaxial growth process. For example, the first S/D structures 140a and the second S/D structure 140b may be the epitaxially grown SiGe doped with boron (B). For example, the first S/D structures 140a and the second S/D structure 140b may be the epitaxially grown Si doped with carbon to form silicon: carbon (Si: C) source/drain features, phosphorous to form silicon: phosphor (Si: P) source/drain features, or both carbon and phosphorous to form silicon carbon phosphor (SiCP) source/drain features. In some embodiments, the first S/D structures 140a and the second S/D structure 140b are doped in one or more implantation processes after the epitaxial growth process.

Afterwards, as shown in FIGS. 2K-1 and 2K-2, after the first S/D structures 140a and the second S/D structure 140b are formed, a contact etch stop layer (CESL) 142 is conformally formed to cover the first S/D structures 140a and the second S/D structure 140b and an interlayer dielectric (ILD) layer 144 is formed over the contact etch stop layers 142, in accordance with some embodiments.

In some embodiments, the contact etch stop layer 142 is made of a dielectric materials, such as silicon nitride, silicon oxide, silicon oxynitride, another suitable dielectric material, or a combination thereof. The dielectric material for the contact etch stop layers 142 may be conformally deposited over the semiconductor structure by performing chemical vapor deposition (CVD), ALD, other application methods, or a combination thereof.

The ILD layer 144 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 144 may be formed by chemical vapor deposition (CVD), physical vapor deposition, (PVD), atomic layer deposition (ALD), or other applicable processes.

After the contact etch stop layer 142 and the ILD layer 144 are deposited, a planarization process such as CMP or an etch-back process may be performed until the gate electrode layers 120 of the dummy gate structures 118 are exposed, as shown in FIG. 2K-1, in accordance with some embodiments.

Afterwards, as shown in FIGS. 2L-1 and 2L-2, the dummy gate structures 118 are removed, in accordance with some embodiments. More specifically, the dummy gate electrode layer 122 and the dummy gate dielectric layer 120 are removed to form gaps 145. Next, the sacrificial layer 136 and the bottommost first semiconductor material layer 106B are removed to form a hole 147. In some embodiment, the sacrificial layer 136 and the bottommost first semiconductor material layer 106B are simultaneously removed to form the hole 147 when the sacrificial layer 136 and the bottommost first semiconductor material layer 106B are made of the same material.

For example, when the dummy gate electrode layers 122 are polysilicon, a wet etchant such as a tetramethylammonium hydroxide (TMAH) solution may be used to selectively remove the dummy gate electrode layers 122. Afterwards, the dummy gate dielectric layers 120 may be removed using a plasma dry etching, a dry chemical etching, and/or a wet etching.

The sacrificial layer 136 and the bottommost first semiconductor material layer 106B may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

Next, as shown in FIGS. 2M-1 and 2M-2, a dielectric layer 148 is formed in the hole 147, in accordance with some embodiments. The dielectric layer 148 provides an isolation to reduce the leakage. The dielectric layer 148 is in direct contact with the inner spacer layer 134 and the bottommost first semiconductor material layer 108B.

In some embodiments, the dielectric layer 148 is formed by formed by an ALD, an ALD-like process or applicable process. Since the thickness of the bottommost first semiconductor material layer 106B is smaller than the thickness of the sacrificial layer 136, a first portion of the hole 147 (which is formed by removing the bottommost first semiconductor material layer 106B) is firstly filled with the dielectric layer 148 than a second portion of the hole 147 (which is formed by removing the sacrificial layer 136). The first portion of the hole 147 is filled with the dielectric layer 148, but the second portion of the hole 147 is not filled with the dielectric layer 148. Therefore, an air gap 149 is formed in the dielectric layer 148. The air gap 149 of the dielectric layer 148 is directly below the first S/D structure 140a and the second S/D structure 140b in the first region 10.

In some embodiments, the dielectric layer 148 has a ring portion 148r and a horizontal portion 148h in the first region 10. The ring portion 148r is directly below the first S/D structure 140a and the second S/D structure 140b, and the horizontal portion 148h is directly below the second semiconductor material layers 108 or the first gate structure 150a. In addition, the horizontal portion 148h of the dielectric layer 148 is directly below the gate spacer layer 126. In some embodiments, the thickness of the ring portion 148r of the dielectric layer 148 is in a range from about 1.5 nm to about 4 nm.

The thickness of the horizontal portion 148h of the dielectric layer 148 is substantially equal to the thickness of the first semiconductor material layer 106. The thickness of the horizontal portion 148h of the dielectric layer 148 is substantially equal to the thickness of the nanostructure 108′ (shown in FIG. 2N-1 and 2N-2). In some embodiments, the thickness of the horizontal portion 148h of the dielectric layer 148 is in a range from about 3 nm to about 8 nm.

The horizontal portion 148h of the dielectric layer 148 has a seam 148s since the first portion of the hole 147 is gradually filled with the dielectric layer 148 from two ends of the hole 147.

The dielectric layer 148 extends from the first position to the second position. The first portion is the ring portion 148r, and the second position is the horizontal portion 148h. In other words, the dielectric layer 148 extends from the position which is directly below the first S/D structure 140a to the position which is directly below the second S/D structure 140b. In addition, the epitaxial layer 137 is between the first S/D structure 140a and the dielectric layer 148. The bottom isolation layer 138 is between the second S/D structure 140b and the dielectric layer 148.

Since the ring portion 148r of the dielectric layer 148 is formed adjacent to the bottommost first semiconductor material layer 108B, the width of the bottommost second semiconductor material layer 108B is greater than the width of the topmost second semiconductor material layer 108.

The top surface of the horizontal portion 148h of the dielectric layer 148 is in direct contact with the bottommost first semiconductor material layer 108B. In addition, a portion of the bottommost first semiconductor material layer 108B is directly below the first S/D structure 140a. The sidewall surface of the dielectric layer 148 extends beyond the sidewall surface of the first S/D structure 140a and the sidewall surface of the second S/D structure 140b.

Afterwards, as shown in FIGS. 2N-1 and 2N-2, the dummy dielectric layers 132 are removed to form nanostructures 108′ (or channel layers 108′) with the second semiconductor material layers 108, in accordance with some embodiments. As a result, a number of gaps 151 are formed between the nanostructures 108′ (or channel layers 108′). The first S/D structures 140a and the second S/D structure 140b are attached to the nanostructures 108′. The first fin structure 104a and the second fin structure 104b include the nanostructures 108′.

In some embodiment, where the nanostructures 108′ (or channel layers 108′) consist essentially of silicon (Si) and the dummy dielectric layers 132 are formed of silicon oxide, the dummy layer 132 is selectively removed by using a selective wet etch process or a selective dry etch process. In some embodiment, the selective dry etching process includes use of carbon tetrafluoride (CF₄), nitrogen trifluoride (NF₃), hydrogen (H₂), or a mixture thereof. In some embodiment, the selective wet etching process includes use of hydrofluoric acid, ammonium fluoride, or a mixture thereof.

Since the dummy dielectric layer 132 and the inner spacer layer 134 are made of different materials and the dummy dielectric layer 132 and the inner spacer layer 134 have different etching selectivity, the dummy dielectric layer 132 is removed but the inner space layer 134 is not removed.

It should be noted that, the gaps 151 are formed by removing the dummy dielectric layer 132, rather than the second semiconductor material layers 106. Therefore, the unwanted by-products, such as Ge-containing residues, which are formed due to removal of the first semiconductor material layers 106, are not remaining in the gaps 151. The clean surfaces of the gaps 151 are provided, and the clean surfaces are helpful for deposition of a first gate structure 150a and a second gate structure 150b (shown in FIGS. 2O-1 and 2O-2).

Furthermore, the first semiconductor material layers 106 is replaced with the dummy dielectric layer 132 before formation of the inner spacer layer 134, the unwanted SiGe/Si intermix products at corner of the inner spacer layer 134 can be reduced. Therefore, the performance of the semiconductor structure 100a is improved.

Next, as shown in FIGS. 2O-1 and 2O-2, after the nanostructures 108′ are formed, the first gate structure 150a and the second gate structure 150b are formed to surround the nanostructures 108′ and over the isolation structure 116, in accordance with some embodiments.

After the nanostructures 108′ are formed, the first gate structure 150a and the second gate structure 150b are formed wrapped around the nanostructures 108′. The first gate structure 150a and the second gate structure 150b wrap around the nanostructures 108′ to form gate-all-around transistor structures, in accordance with some embodiments. In some embodiments, each of the first gate structure 150a and the second gate structure 150b includes an interfacial layer 152, a gate dielectric layer 154, and a gate electrode layer 156.

In some embodiments, the interfacial layer 152 are oxide layers formed around the nanostructures 108′ and on the top of the base fin structure 105. In some embodiments, the interfacial layer are formed by performing a thermal process.

In some embodiments, the gate dielectric layers 154 are formed over the interfacial layers, so that the nanostructures 108′ are surrounded (e.g. wrapped) by the gate dielectric layers 154. In addition, the gate dielectric layers 154 also cover the sidewalls of the gate spacers 126 and the inner spacers 134, in accordance with some embodiments.

In some embodiments, the gate dielectric layers 154 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. In some embodiments, the gate dielectric layers 154 are formed using chemical vapor deposition (CVD), atomic layer deposition (ALD), another applicable method, or a combination thereof.

In some embodiments, the gate electrode layer 156 is made of one or more layers of conductive material, such as aluminum, copper, titanium, tantalum, tungsten, cobalt, molybdenum, tantalum nitride, nickel silicide, cobalt silicide, TiN, WN, TiAl, TiAIN, TaCN, TaC, TaSiN, metal alloys, another suitable material, or a combination thereof. In some embodiments, the gate electrode layer 156 is formed using chemical vapor deposition (CVD), atomic layer deposition (ALD), electroplating, another applicable method, or a combination thereof.

Other conductive layers, such as work function metal layers, may also be formed in the first gate structure 150a and the second gate structure 150b, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAIN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

After the interfacial layer 152, the gate dielectric layers 154, and the gate electrode layer 156 are formed, a planarization process such as CMP or an etch-back process may be performed until the ILD layer 144 is exposed.

Afterwards, as shown in FIGS. 2P-1 and 2P-2, an etch stop layer 160 is formed over the first gate structure 150a, the second gate structure 150b, and a dielectric layer 162 is formed over the etch stop layer 160, in accordance with some embodiments.

In some embodiments, the etch stop layer 160 is made of a dielectric materials, such as silicon nitride, silicon oxide, silicon oxynitride, another suitable dielectric material, or a combination thereof. The dielectric material for the etch stop layers 160 may be conformally deposited over the semiconductor structure by performing chemical vapor deposition (CVD), ALD, other application methods, or a combination thereof.

The dielectric layer 162 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 162 may be formed by chemical vapor deposition (CVD), physical vapor deposition, (PVD), atomic layer deposition (ALD), or other applicable processes.

Next, a silicide layer 164 and an S/D contact structure 166 are formed through the first S/D structure 140a and the second S/D structure 140b, in accordance with some embodiments. More specifically, the S/D contact structure 166 is formed through the top portion of first S/D structure 140a and the top portion of the second S/D structure 140b.

In some embodiments, the contact openings may be formed through the dielectric layer 162, the etch stop layer 160, the interlayer dielectric layer 144, the contact etch stop layer 142, the first S/D structures 140a and the second S/D structure 140b, and then the silicide layers 164 and the S/D contact structure 166 may be formed in the contact openings.

The contact openings may be formed using a photolithography process and an etching process. In addition, some portions of the first S/D structure 140a and second S/D structure 140b exposed by the contact openings may also be etched during the etching process.

The silicide layers 164 may be formed by forming a metal layer over the top surfaces of the first S/D structure 140a and the second S/D structure 140b and annealing the metal layer so the metal layer reacts with the first S/D structure 140a and the second S/D structure 140b to form the silicide layers 164. The unreacted metal layer may be removed after the silicide layers 164 are formed. In some embodiments, the silicide layers 164 has a U-shaped structure.

The S/D contact structure 166 may include a barrier layer and a conductive layer. In some other embodiments, the S/D contact structure 166 does not include a barrier layer. In some embodiments, the barrier layer is made of titanium (Ti), titanium nitride (TiN), tantalum (Ta), tantalum nitride (TaN), or another applicable material. In some embodiments, the barrier layer is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. In some embodiments, the conductive layer is made of tungsten (W), ruthenium (Ru), molybdenum (Mo), or the like. In some embodiments, the conductive layer is formed by performing a deposition process, such as chemical vapor deposition (CVD), physical vapor deposition, (PVD), atomic layer deposition (ALD), or other applicable processes.

It should be noted that the dielectric layer 148 is used to define the effective (or active) nanostructure number (e.g. nanosheet number) and to achieve multi-nanostructures (e.g. nanosheets) co-exist. In the first region 10, the dielectric layer 148 provides an isolation function, and therefore the first S/D structure 140a is isolated from the base fin structure 104B by the dielectric layer 148. The bottommost nanostructure 108′ in the first region 10 is in direct contact with the dielectric layer 148, the bottommost nanostructure 108′ become inactive, and cannot use as an active channel layer.

In the first region 10, there are three nanostructures 108′ (e.g. three second semiconductor material layers 108 in the first region 10), but the effective (or active) nanostructure number becomes two due to the formation of the dielectric layer 148. In the second region 20, there are three nanostructures (e.g. three second semiconductor material layers 108 in the second region 20), and the effective (or active) nanostructure number is also three. Therefore, the effective (or active) nanostructure number in the second region 20 is greater than the effective (or active) nanostructure number in the first region 10.

More nanostructures (e.g. three second semiconductor material layers 108′ in the second region 20) can provide large effective width (Weff) of the channel. The large effective width (Weff) of channel can provide high speed of the semiconductor structure. However, the larger effective width of the channel consumes more power. For high speed performance consideration, larger effective width (Weff) is formed by having more nanostructures. For power efficiency, a smaller effective width (Weff) is formed by having fewer nanostructures.

In order to fulfill different needs in a region, the effective nanostructure number can be controlled by defining the locations of the dielectric layer 148. The effective nanostructure number of semiconductor structure 100a in the first region 10 is fewer than the effective nanostructure number of the semiconductor structure 100a in the second region 20. Therefore, the semiconductor structure 100a in the first region 10 is formed for power efficiency and the semiconductor structure 100a in the second region 20 is formed for high speed performance. The semiconductor structure 100a with different effective nanostructure number co-exist to achieve multi-nanostructures for speed performance and power efficiency. Furthermore, due to formation of the dielectric layer 148, the unwanted parasitic capacitance is reduced.

FIG. 2P′-1 and 2P′-2 illustrate a cross-sectional views of a semiconductor structure 100b, in accordance with some embodiments. The semiconductor structure 100b of FIG. 2P′-1 and 2P′-2 includes elements that are similar to, or the same as, elements of the semiconductor structure 100a of FIGS. 2P-1 and 2P-2, the difference between FIG. 2P′-1 and 2P′-2 and FIG. 2P-1 and 2P-2 is that the bottom isolation layer 138 has a convex top surface. The first S/D structure 140a is formed on the convex top surface of the bottom isolation layer 138 in the first region 10, and the second S/D structure 140b is formed on the convex top surface of the bottom isolation layer 138 in the second region 20.

FIG. 2P″-1 and 2P″-2 illustrate a cross-sectional views of a semiconductor structure 100c, in accordance with some embodiments. The semiconductor structure 100c of FIG. 2P″-1 and 2P″-2 includes elements that are similar to, or the same as, elements of the semiconductor structure 100a of FIGS. 2P-1 and 2P-2, the difference between FIG. 2P″-1 and 2P″-2 and FIG. 2P-1 and 2P-2 is that the bottom isolation layer 138 has a concave top surface. The first S/D structure 140a is formed on the concave top surface of the bottom isolation layer 138 in the first region 10, and the second S/D structure 140b is formed on the concave top surface of the bottom isolation layer 138 in the second region 20.

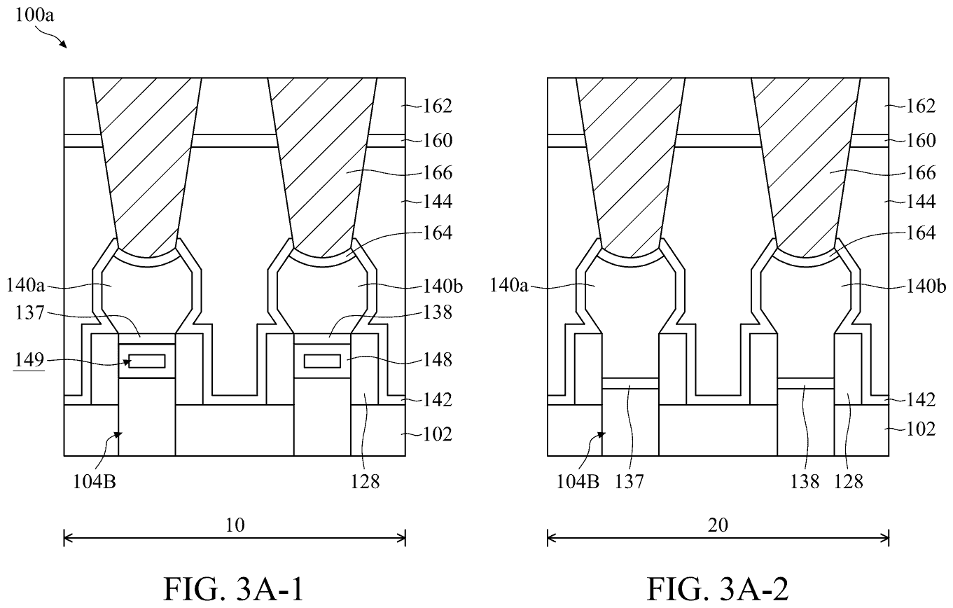

FIGS. 3A-1 and 3A-2 illustrate cross-sectional representations of the semiconductor structure 100a shown along line C-C′ in FIG. 1E in accordance with some embodiments.

As shown in FIGS. 3A-1 and 3A-2, the fin spacers 128 are formed on the sidewall surfaces of the first S/D structure 140a in the first region 10, and on the sidewall surfaces of the second S/D structure 140b in the second region 20.

In the first region 10, the dielectric layer 148 is below the epitaxial layer 137 and the first S/D structure 140a, and the air gap 149 is below the first S/D structure 140a and enclosed by the dielectric layer 148. The dielectric layer 148 is below the bottom isolation layer 138 and the second S/D structure 140b, and the air gap 149 is below the second S/D structure 140b and enclosed by the dielectric layer 148. In other words, the air gap 149 is directly below the S/D contact structure 166. In some embodiments, the air gap 149 has a height in a range from about 5 nm to about 15 nm. In some embodiments, the air gap 149 has a width in a range from about 8 nm to about 22 nm.

In the second region 20, the epitaxial layer 137 is directly below the first S/D structure 140a, and bottom isolation layer 138 is below the second S/D structure 140b. The bottommost surface of the first S/D structure 140a in the second region 20 is lower than the bottommost surface of the first S/D structure 140a in the first region 10. In addition, the bottommost surface of the second S/D structure 140b in the second region 20 is lower than the bottommost surface of the second S/D structure 140b in the first region 10.

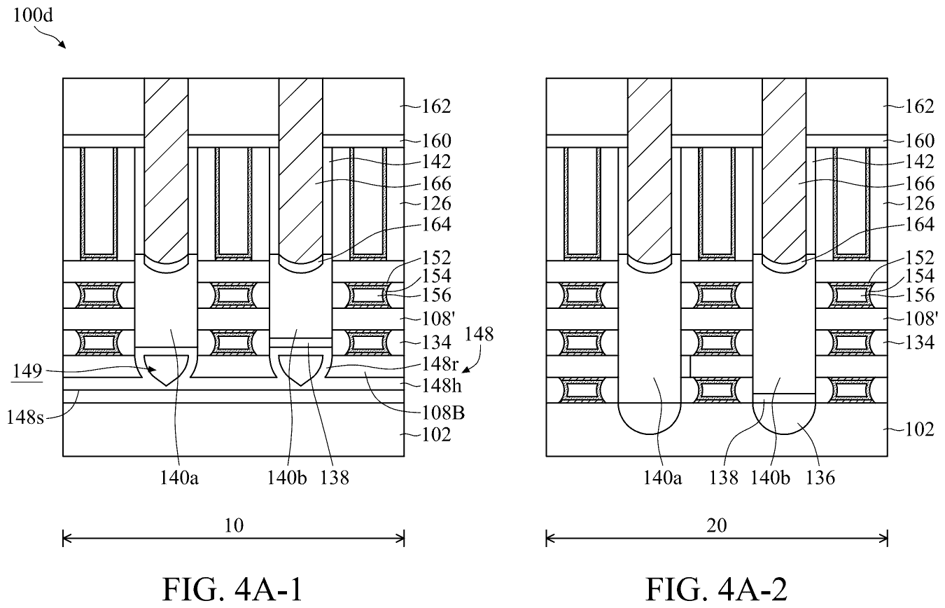

FIG. 4A-1 and 4A-2 illustrate a cross-sectional views of a semiconductor structure 100d, in accordance with some embodiments. The semiconductor structure 100d of FIG. 4A-1 and 4A-2 includes elements that are similar to, or the same as, elements of the semiconductor structure 100a of FIGS. 2P-1 and 2P-2, the difference between FIG. 4A-1 and 4A-2 and FIG. 2P-1 and 2P-2 is that there is no epitaxial layer formed between the dielectric layer 148 and the first S/D structure 140a in the first region 10, and there is no epitaxial layer formed between the dielectric layer 148 and the first S/D structure 140a.

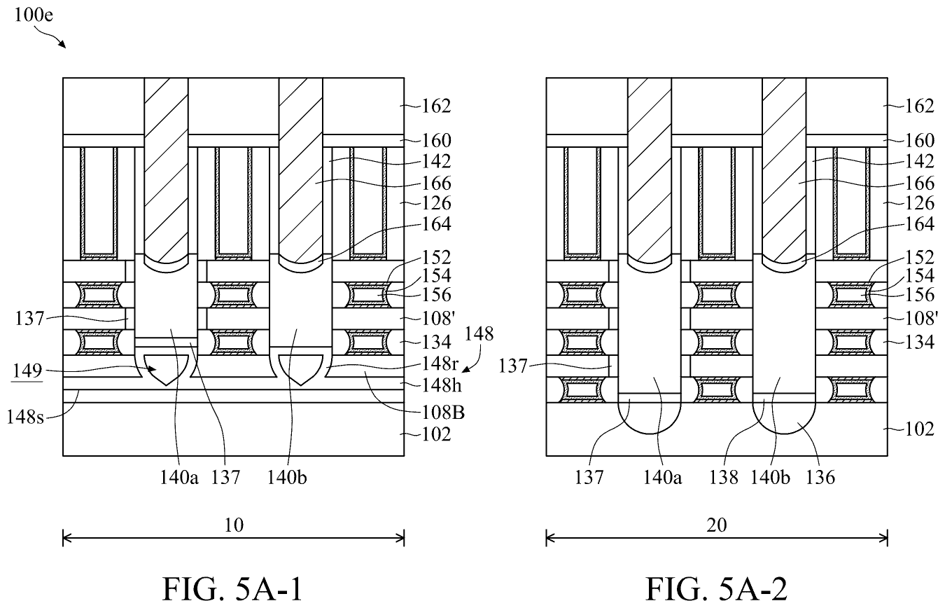

FIG. 5A-1 and 5A-2 illustrate a cross-sectional views of a semiconductor structure 100e, in accordance with some embodiments. The semiconductor structure 100e of FIG. 5A-1 and 5A-2 includes elements that are similar to, or the same as, elements of the semiconductor structure 100a of FIGS. 2P-1 and 2P-2, the difference between FIG. 5A-1 and 5A-2 and FIG. 2P-1 and 2P-2 is that there is no bottom isolation layer between the second S/D structure 140b and the dielectric layer 148 in the first region 10. In the second region 20, the bottom isolation layer 138 is between the second S/D structure 140b and the dielectric layer 148. In some other embodiments, there is no bottom isolation layer between the second S/D structure 140b and the dielectric layer 148 in the second region 20.

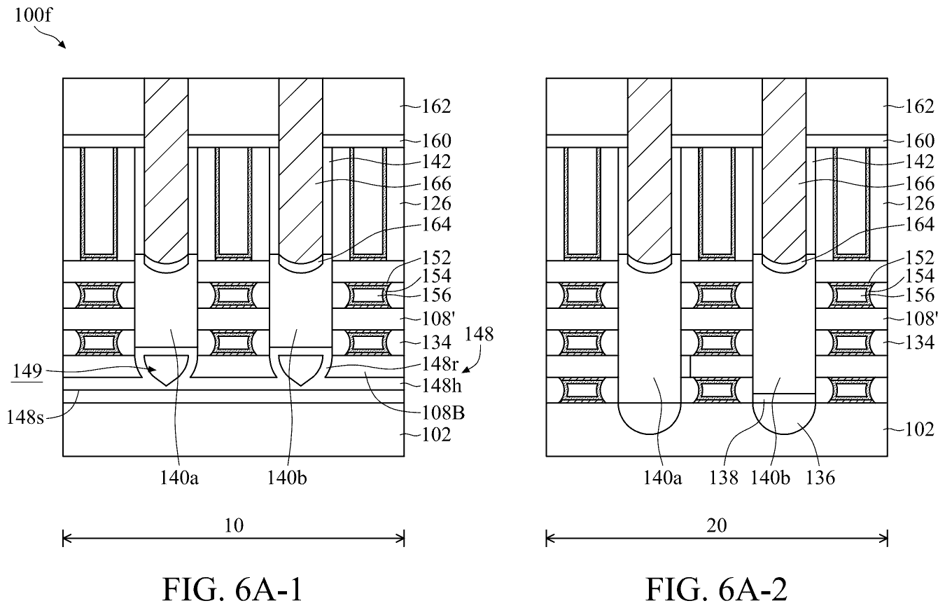

FIG. 6A-1 and 6A-2 illustrate a cross-sectional views of a semiconductor structure 100f, in accordance with some embodiments. The semiconductor structure 100f of FIG. 6A-1 and 6A-2 includes elements that are similar to, or the same as, elements of the semiconductor structure 100a of FIGS. 2P-1 and 2P-2, the difference between FIG. 6A-1 and 6A-2 and FIG. 2P-1 and 2P-2 is that there is no epitaxial layer formed between the dielectric layer 148 and the first S/D structure 140a in the first region 10 and there is no bottom isolation layer between the second S/D structure 140b and the dielectric layer 148 in the first region 10. In some other embodiments, there is no bottom isolation layer between the second S/D structure 140b and the dielectric layer 148 in the second region 20.

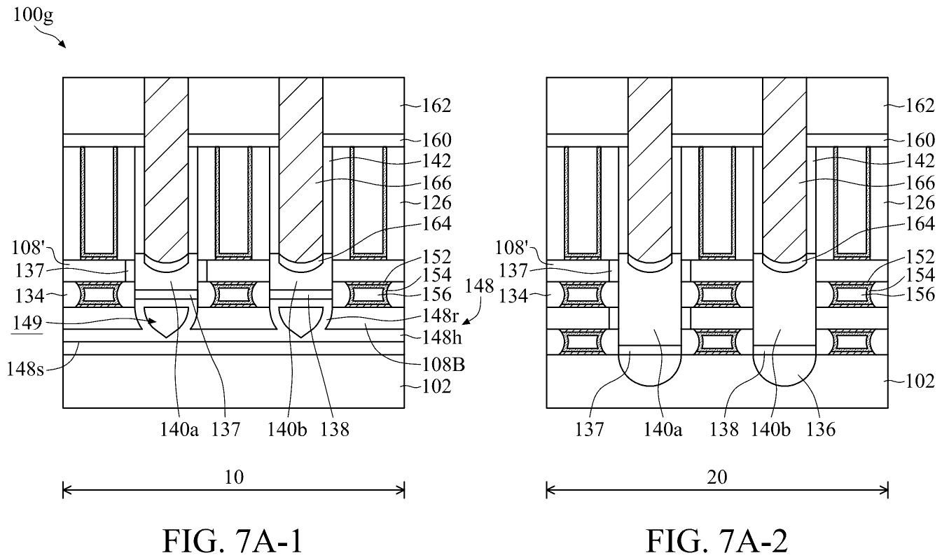

FIG. 7A-1 and 7A-2 illustrate a cross-sectional views of a semiconductor structure 100g, in accordance with some embodiments. The semiconductor structure 100g of FIG. 7A-1 and 5A-2 includes elements that are similar to, or the same as, elements of the semiconductor structure 100a of FIGS. 2P-1 and 2P-2, the difference between FIG. 7A-1 and 7A-2 and FIG. 2P-1 and 2P-2 is that the effective (or active) nanostructure number in the first region 10 is one, and the effective (or active) nanostructure number in the second region 20 is two.

In the first region 10, there are two nanostructures (e.g. two second semiconductor material layers 108 in the first region 10), but the effective (or active) nanostructure number becomes one due to the formation of the dielectric layer 148. In the second region 20, there are two nanostructures (e.g. three second semiconductor material layers 108 in the second region 20), and the effective (or active) nanostructure number is also two. Therefore, the effective (or active) nanostructure number in the second region 20 is greater than the effective (or active) nanostructure number in the first region 10.

The dielectric layer 148 is directly below the first S/D structure 140a in the first region 10, and the bottommost nanostructure 108′ is in direct contact with the dielectric layer 148. The bottommost nanostructure 108′ become inactive, and a portion of the bottommost nanostructure 108′ directly below the first S/D structure 140a.

The dielectric layer 148 extends from the first S/D structure 140a to the second S/D structure 140b, and the dielectric layer 148 has a portion which is directly below the first gate structure 150a. Therefore, the unwanted parasitic capacitance is further reduced, and the performance of the semiconductor structure is improved.

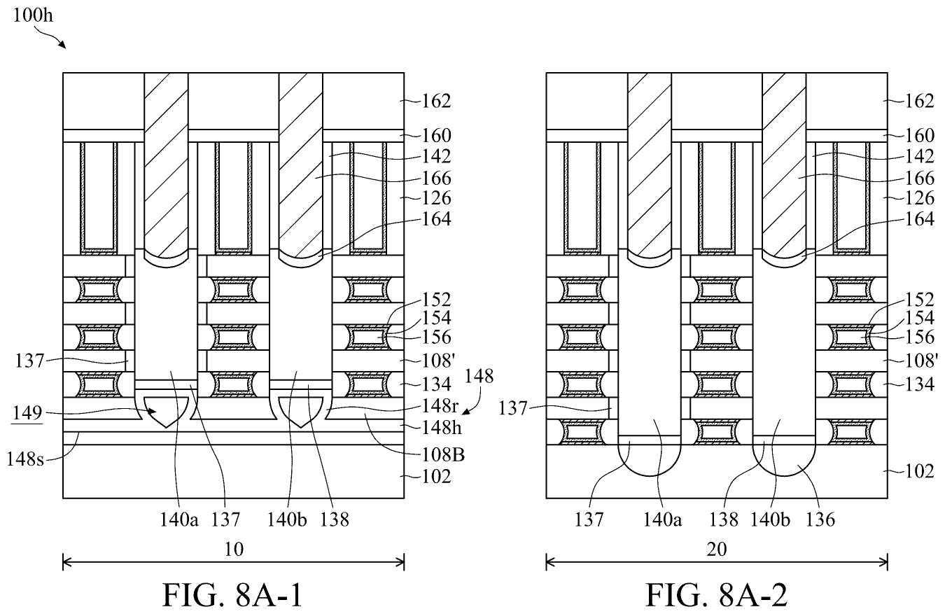

FIG. 8A-1 and 8A-2 illustrate a cross-sectional views of a semiconductor structure 100h, in accordance with some embodiments. The semiconductor structure 100h of FIG. 8A-1 and 8A-2 includes elements that are similar to, or the same as, elements of the semiconductor structure 100a of FIGS. 2O-1 and 2O-2, the difference between FIG. 8A-1 and 8A-2 and FIGS. 2O-1 and 2O-2 is that the effective (or active) nanostructure number in the first region 10 is three, and the effective (or active) nanostructure number in the second region 20 is four.

In the first region 10, there are four nanostructures (e.g. four second semiconductor material layers 108 in the first region 10), but the effective (or active) nanostructure number becomes three due to the formation of the dielectric layer 148. In the second region 20, there are four nanostructures (e.g. three second semiconductor material layers 108 in the second region 20), and the effective (or active) nanostructure number is also four. Therefore, the effective (or active) nanostructure number in the second region 20 is greater than the effective (or active) nanostructure number in the first region 10.

It should be appreciated that the semiconductor structures 100a to 100h having the dielectric layer 148 with air gap 149 below the first S/D structure 140a and the second S/D structure 140b in the first region 10. Since the dielectric layer 148 is in direct contact with the bottommost nanostructure 108′, the bottommost nanostructure 108′ become inactive, and cannot be used as channel layer. Therefore, the effective (or active) nanostructure number can be adjusted by formation of the dielectric layer 148. In addition, the unwanted parasitic capacitance is reduced by forming the dielectric layer 148 directly below the first gate structure 150a.

It should be noted that same elements in FIGS. 1A to 8A-2 may be designated by the same numerals and may include similar or the same materials and may be formed by similar or the same processes; therefore such redundant details are omitted in the interest of brevity. In addition, although FIGS. 1A to 8A-2 are described in relation to the method, it will be appreciated that the structures disclosed in FIGS. 1A to 8A-2 are not limited to the method but may stand alone as structures independent of the method. Similarly, although the methods shown in FIGS. 1A to 8A-2 are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structures may include a substrate includes a first region and a second region. A number of first nanostructures are formed on the first region, and a number of second nanostructures are formed on the second region. A first S/D structure formed adjacent to the first nanostructures, and a second S/D structure formed adjacent to the second nanostructures. A dielectric layer is formed below the first S/D structure in the first region, and the dielectric layer has an air gap. The dielectric layer is in direct contact with the bottommost first nanostructure in the first region, and thus the bottommost first nanostructure become inactive. The sacrificial layer and the bottommost first semiconductor material layer is formed and are replaced with the dielectric layer. The dielectric layer has an air gap below the first S/D structure. The bottommost nanostructure is in direct contact with the dielectric layer, and the bottommost nanostructure become inactive.

The effective (or active) nanostructures are controlled by defining the location of the dielectric layer in the first region. In the second region, no dielectric layer is directly below the second S/D structure, and the bottommost second nanostructure still active. Therefore, the semiconductor structure includes more effective (or active) nanostructures in the second region for speed performance considerations and fewer effective (or active) nanostructures in the first region for power efficiency consideration. Therefore, the performance of semiconductor structure is improved.

In some embodiments, a semiconductor structure is provided. The semiconductor structure includes a plurality of first nanostructures formed over a substrate, and a first gate structure formed on the first nanostructures. The semiconductor structure includes a first S/D structure formed adjacent to the first gate structure. The semiconductor structure includes a dielectric layer directly below the first S/D structure. The dielectric layer has an air gap. The dielectric layer is in direct contact with the bottommost first nanostructure.

In some embodiments, a semiconductor structure is provided. The semiconductor structure includes a plurality of nanostructures formed over a substrate, and a first gate structure formed over the nanostructures. The semiconductor structure includes a first source/drain (S/D) structure formed adjacent to the gate structure and an air gap directly below the first S/D structure. The air gap is enclosed by a dielectric layer, and a sidewall surface of the dielectric layer extends beyond a sidewall surface of the first S/D structure.

In some embodiments, a method for forming a semiconductor structure is provided. The method includes forming a plurality of first semiconductor material layers and a plurality of second semiconductor material layers on a substrate, and the first semiconductor material layers and the second semiconductor material layers are alternately stacked. The method includes forming a dummy gate structure over the first semiconductor material layers and the second semiconductor material layers, and removing a portion of the first semiconductor material layers and the second semiconductor material layers to form a trench. The bottom surface of the trench is higher than the top surface of the bottommost first semiconductor material layer. The method includes removing a portion of the second semiconductor material layers to enlarge the depth of the trench, and the bottommost first semiconductor material layer is exposed by the trench. The method includes forming a sacrificial layer in the trench, and forming an S/D structure over the sacrificial layer. The method includes removing the dummy gate structure, and removing the sacrificial layer and the bottommost first semiconductor material layer to form a hole. The method includes forming a dielectric layer in the hole, wherein the dielectric layer has an air gap.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a plurality of first nanostructures formed over a substrate;
a first gate structure formed on the first nanostructures;
a first S/D structure formed adjacent to the first gate structure; and
a dielectric layer below the first S/D structure, wherein the dielectric layer has an air gap, and the dielectric layer is in contact with a bottommost first nanostructure.

2. The semiconductor structure as claimed in claim 1, wherein a width of the bottommost first nanostructure is greater than a topmost first nanostructure.

3. The semiconductor structure as claimed in claim 1, further comprising:
a second S/D structure formed adjacent to the first S/D structure, wherein a bottom isolation layer is between the dielectric layer and the second S/D structure.

4. The semiconductor structure as claimed in claim 1, wherein the dielectric layer has a ring portion and a horizontal portion, the ring portion is directly below the first S/D structure, and the horizontal portion is directly below the first nanostructures.

5. The semiconductor structure as claimed in claim 4, wherein a thickness of the horizontal portion of the dielectric layer is substantially equal to a thickness of one of the first nanostructures.

6. The semiconductor structure as claimed in claim 1, further comprising:
an epitaxial layer between the dielectric layer and the first S/D structure.

7. The semiconductor structure as claimed in claim 1, further comprising:
a plurality of second nanostructures formed over the substrate;
a second gate structure formed on the second nanostructures; and
a second S/D structure formed adjacent to the second gate structure, wherein effective nanostructure number of the second nanostructures is greater than the effective nanostructure number of the first nanostructure.

8. The semiconductor structure as claimed in claim 1, further comprising:
an inner spacer layer between the first S/D structure and the first gate structure, wherein the inner spacer layer is in contact with the dielectric layer.

9. The semiconductor structure as claimed in claim 1, further comprising:
a gate spacer layer adjacent to the first gate structure, wherein the dielectric layer is below the gate spacer layer.

10. A semiconductor structure, comprising:
a plurality of nanostructures formed over a substrate;
a first gate structure formed over the nanostructures;
a first source/drain (S/D) structure formed adjacent to the gate structure; and
an air gap below the first S/D structure, wherein the air gap is enclosed by a dielectric layer, and a sidewall surface of the dielectric layer extends beyond a sidewall surface of the first S/D structure.

11. The semiconductor structure as claimed in claim 10, wherein a portion of the bottommost first nanostructure is directly below the first S/D structure.

12. The semiconductor structure as claimed in claim 10, wherein the dielectric layer is in contact with the bottommost first nanostructure.

13. The semiconductor structure as claimed in claim 10, further comprising:
an inner spacer layer between the first S/D structure and the first gate structure, wherein the inner spacer layer is in contact with the dielectric layer.

14. The semiconductor structure as claimed in claim 10, further comprising:
a plurality of second nanostructures formed over the substrate;
a second gate structure formed on the second nanostructures; and
a second S/D structure formed adjacent to the second gate structure, wherein effective nanostructure number of the second nanostructures is greater than the effective nanostructure number of the first nanostructures.

15. The semiconductor structure as claimed in claim 14, wherein the dielectric layer extends from a first position to a second position, the first position is directly below the first S/D structure, and the second position is directly below the second S/D structure.

16. The semiconductor structure as claimed in claim 10, wherein the dielectric layer has a ring portion and a horizontal portion, and the horizontal portion has a seam.

17. A method for forming a semiconductor structure, comprising:
forming a plurality of first semiconductor material layers and a plurality of second semiconductor material layers on a substrate, wherein the first semiconductor material layers and the second semiconductor material layers are alternately stacked;
forming a dummy gate structure over the first semiconductor material layers and the second semiconductor material layers;
removing a portion of the first semiconductor material layers and the second semiconductor material layers to form a trench, wherein a bottom surface of the trench is higher than a top surface of a bottommost first semiconductor material layer;
removing a portion of the second semiconductor material layers to enlarge a depth of the trench, wherein the bottommost first semiconductor material layer is exposed by the trench;
forming a sacrificial layer in the trench;
forming an S/D structure over the sacrificial layer;
removing the dummy gate structure;
removing the sacrificial layer and the bottommost first semiconductor material layer to form a hole and
forming a dielectric layer in the hole, wherein the dielectric layer has an air gap.

18. The method for forming the semiconductor structure as claimed in claim 17, further comprising:
removing the second semiconductor material layers to form a recess between two adjacent first semiconductor material layers;
forming a dummy dielectric layer in the recess;
removing a portion of the dummy dielectric layer to form a cavity; and
forming an inner spacer layer in the cavity.

19. The method for forming the semiconductor structure as claimed in claim 18, further comprising:
removing the dummy gate structure; and
removing the dummy dielectric layer after removing the dummy gate structure.

20. The method for forming the semiconductor structure as claimed in claim 17, further comprising:
forming a bottom isolation layer over the sacrificial layer; and
forming the S/D structure over the bottom isolation layer.
